(19) United States
(12) Patent Application Publication
(10) Pub. No.: US 2025/0342296 A1
(43) Pub. Date: Nov. 6, 2025

(54) METHOD AND SYSTEM OF SIMULATING OPERATIONAL INTEGRITY OF A PRE-FILLED VIAL

(71) Applicant: Pfizer Inc., New York, NY (US)

(72) Inventor: Kirk ROFFI, Billerica, MA (US)

(73) Assignee: Pfizer Inc., New York, NY (US)

(21) Appl. No.: 19/196,932

(22) Filed: May 2, 2025

Related U.S. Application Data
(60) Provisional application No. 63/642,186, filed on May 3, 2024.

(51) Int. Cl. G06F 30/28

(52) U.S. Cl. CPC G06F 30/28

(57) ABSTRACT

Method and system of digitally simulating operational integrity of a pre-filled vial. The method includes simulating, in a processor of a computing system, a frictional disengaging of a stopper from the pre-filled vial responsive to a progressively decreasing ambient pressure, the pre-filled vial containing a gaseous portion that is separated from ambient air by the stopper, and generating, by the processor in accordance with the progressively decreasing ambient pressure, a measure corresponding to an aircraft altitude at which the frictional disengaging is initiated.

### TECHNICAL FIELD

The disclosure herein relates to digital simulation of physical effects upon container systems and devices.

### BACKGROUND

Shipment of pre-filled vials frequently includes, at least partially, high altitude transportation by aircraft. During high altitude transportation of pre-filled vials, such as pre-filled syringes partially filled with liquid or fluid drug constituents and further having an air gap or gaseous portion contained therewithin, pressure differentials can induce undesirable displacement of a stopper deployed for enclosing the contents, potentially compromising vial integrity and/or sterility of vial constituents. Current experimental techniques for physically quantifying appropriate altitude limitations during high altitude transportation may be expensive and time- and manpower-consuming to conduct. Such physical experimental techniques may also be subject to inaccuracies and errors unintentionally introduced due to reliability, repeatability and tolerance variation limitations inherent to laboratory equipment deployed in the experiment-based techniques.

### BRIEF DESCRIPTION OF THE DRAWINGS

FIG. 1 illustrates, in an example embodiment, a pre-filled vial device.

FIG. 2 illustrates, in an example embodiment, a scheme for digital simulation of physical characteristics related to operational integrity of a pre-filled vial.

FIG. 3 illustrates, in an example embodiment, a computing device architecture for digital simulation of operational integrity of a pre-filled vial.

FIG. 4 illustrates, in an example embodiment, an architecture of a proportional-integral-derivative (PID) controller block for digital simulation of operational integrity of a pre-filled vial.

FIG. 5 illustrates, in an example embodiment, a method of operation in digital simulation of operational integrity of a pre-filled vial.

### DETAILED DESCRIPTION

To enable global distribution of pre-filled vials, accurate and cost-effective methods of quantizing high-altitude limits in order to maintain and ensure operational integrity of the pre-filled vial and its contents during high altitude transit are needed. Among other benefits and advantages, embodiments herein provide a digital simulation model to simulate effects of high-altitude shipment on container closure integrity of pre-filled vials and syringes, for realistic and accurate results in determining stopper displacement profiles during high altitude transportation. Embodiments herein further provide simulation tools by enabling rapid and accurate risk assessment of global distribution of pre-filled syringes, vials and similar enclosed containers. In particular, embodiments herein provide and deploy a modeling framework derived from a tribology perspective and friction compensation methods, applying data-based friction compensation via a proportional-integral-derivative (PID) controller block to simulate the displacement profile of a stopper that encloses the vial contents.

Provided is a method of digitally simulating operational integrity of a pre-filled vial. The method comprises simulating, in a processor of a computing system, a frictional disengaging of a stopper that is engaged with the pre-filled vial responsive to a progressively decreasing ambient pressure, the pre-filled vial containing a gaseous portion that is separated from ambient air by the stopper, and generating, by the processor in accordance with the progressively decreasing ambient pressure, a measure corresponding to an aircraft altitude at which the frictional disengaging is initiated.

Also provided is a computing system for digitally simulating operational integrity of a pre-filled vial, the computing system including a processor and a non-transitory memory including instructions executable in the processor. The instructions when executed by the processor cause the processor to perform operations comprising instantiating a simulation module that simulates frictional disengaging of a stopper that is engaged with a pre-filled vial responsive to a progressively decreasing ambient pressure, the pre-filled vial including a gaseous portion that is separated from ambient air by the stopper, and instantiating an output module that generates, in accordance with the progressively decreasing ambient pressure, a measure corresponding to an aircraft altitude at which the frictional disengaging is initiated.

In embodiments, the pre-filled vial comprises a pre-filled syringe. The vial may be constructed of a glass or a polymer material, and also any combination thereof. The stopper may be constructed of an elastomer material, such as, but not limited to, rubber.

In some embodiments, the digital simulation model may based on a proportional-integral-derivative (PID) controller block that includes a PID observer. In some aspects, the PID observer models frictional mechanics of the stopper relative to a surface of the pre-filled vial with which the stopper is engaged in accordance with a PID friction compensation model. In some particular embodiments, the PID friction compensation model is based at least in part upon elastomer-glass surface asperities and frictional characteristics inherent thereto.

Also provided is a non-transitory computer-readable memory storing instructions, the instructions being executable in one or more processor devices to cause the one or more processor to perform operations comprising instantiating a simulation module that simulates frictional disengaging of a stopper that is engaged with a pre-filled vial responsive to a progressively decreasing ambient pressure, the pre-filled vial including a gaseous portion that is separated from ambient air by the stopper, and instantiating an output module that generates, in accordance with the progressively decreasing ambient pressure, a measure corresponding to an aircraft altitude at which the frictional disengaging is initiated.

Embodiments described herein can be implemented using programmatic modules, through the use of instructions that are executable by one or more processors. A programmatic module can include a program, a sub-routine, a portion of a program, or a software component or a hardware component capable of performing one or more stated tasks or functions. As used herein, a programmatic module can exist on a hardware component independently of other modules or components, or can be a shared element of other modules, programs or machines.

One or more embodiments described herein provide that methods, techniques, and actions performed in a digital simulation computing system are performed programmatically, or as a computer-implemented method. Programmatically, as used herein, means through the use of code or computer-executable instructions. These instructions can be stored in one or more memory resources incorporated in, or accessible to, the digital simulation computing system.

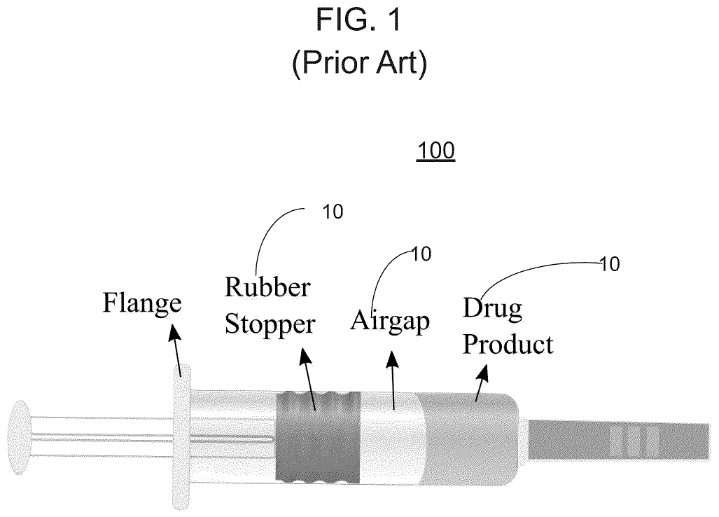

FIG. 1 illustrates, in an example embodiment, a pre-filled vial device 100, a pre-filled syringe in the embodiment depicted. In operation, vial 100 may contain drug product 103, with an air or other gaseous gap 101 formed within the vial, with both the air gap 101 and drug product 103 being enclosed within vial 100 by rubber stopper 101. The air gap 101 may be introduced during filling of the syringe with the drug constituents, an operation performed typically at higher ambient pressure, for example, at manufacturing facilities located at sea level or close thereto. As will be appreciated by those of skill in the art, once a transport aircraft ascends to increasingly higher altitudes, ambient pressure under high altitude conditions are significantly less than ambient pressure of gas in the air gap introduced during manufacturing. The pressure differential between gas in the enclosed air gap 102 and the progressively lower (as the aircraft ascends) high altitude ambient pressure outside of the stopper 101 causes a correspondingly increasing force that tends to push the stopper outwards of the vial. Once the pressure differential-based force overcomes the static frictional forces keeping the stopped engaged, the stopper 101 is displaced outwards of the vial, whereupon the vial contents can be placed at high risk of compromise.

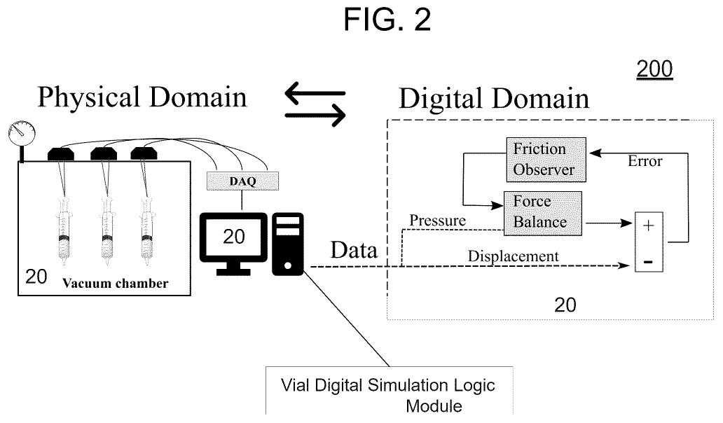

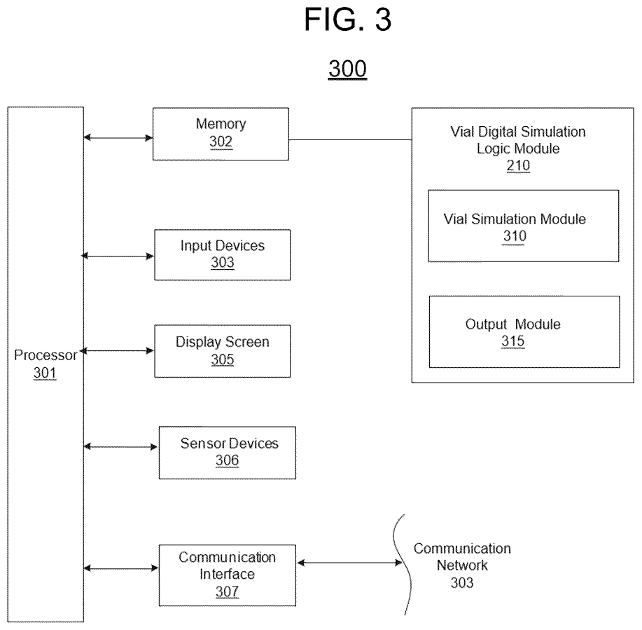

FIG. 2 illustrates, in an example embodiment, an overall or overview scheme 200 for digital simulation of physical characteristics related to operational integrity of pre-filled vial 100. Digital simulation computing system 201 includes vial digital simulation logic module 210 which consists of instructions, stored in a computer readable memory, the instructions being executable in a processor of digital simulation computing system 201. PID controller block 205 which includes a PID friction observer, is deployed to simulate or model the operational integrity of pre-filled vial 100, as will be described in further detail with reference to FIGS. 3 through 5 herein. Physical domain 206 provides laser displacement data representative of the underlying tribology and sliding contact between vial and stopper at areas of engagement or overlap.

FIG. 3 illustrates, in an example embodiment, computing system architecture 300 for digital simulation of operational integrity of a pre-filled vial. In an example embodiment, computing system architecture 300 may be implemented in computing system 201, which may be server computing device, a desktop computing device, a laptop computing device, or similar computing device. Computing system 201, in embodiments, may include processor 301, memory 302, input devices 303, display screen 305 and be communicatively interconnected via communication interface 307 that is communicatively coupled with communication network 303.

In embodiments, computing system 201 can be interfaced or communicatively coupled with sensor devices 306, including pressure and laser displacement sensor devices. Laser displacement data can be acquired from physical domain 206 of the embodiment depicted in FIG. 2, representative of the underlying tribology including stopper sliding contact characteristics for a given pair of engagement surfaces formed by way of overlap between stopper 101 within vial 100. In one embodiment, the stopper may be of rubber or similar elastomer material, the vial of constructed of glass, and the PID friction compensation or observer model is based at least in part upon elastomer-glass surface asperities. Sensor data, pressure and displacement, may be fused with the system dynamics to infer friction via the PID friction observer of the PID controller block.

Processor 301 can be implemented in an application specific integrated circuit (ASIC) device or field programmable gate array (FPGA) device, in some embodiments. Memory 302 may comprise any type of non-transitory computer readable memory, storing instructions that are executable in processor 301, including such as a static random access memory (SRAM), dynamic random access memory (DRAM), synchronous DRAM (SDRAM), read-only memory (ROM), or any combination thereof.

Vial digital simulation logic module 210 of digital simulation computing system 201, in embodiments, may be include vial simulation module 310 and output module 315. Vial simulation module 310 and output module 315 are constituted of processor-executable instructions stored in memory 302 and instantiated by way of execution of their respective instructions in processor 301.

Vial simulation module 310, in embodiments, may be constituted of processor-executable instructions for instantiating a simulation module that simulates frictional disengaging of a stopper that is engaged with a pre-filled vial responsive to a progressively decreasing ambient pressure, the pre-filled vial including a gaseous portion that is separated from ambient air by the stopper.

Output module 315 in embodiments, may be constituted of processor-executable instructions for instantiating an output module that generates, in accordance with the progressively decreasing ambient pressure, a measure corresponding to an aircraft altitude at which the frictional disengaging is initiated. Output module 315 provides a set of outputs from the PID controller block, the set of outputs comprising one or more of a stopper displacement, a stopper velocity and stopper friction characteristics, such as in relation to transitions from static friction to sliding friction forces. A corresponding aircraft altitude at which the frictional disengaging is initiated can be inferred and generated based on predictions of one or more of the outputs in relation to the ambient pressure at an altitude for which stopper displacement is initiated.

In embodiments, the pre-filled vial comprises a pre-filled syringe. The vial may be constructed of a glass or a polymer material, and also any combination thereof. The stopper may be constructed of an elastomer material, such as, but not limited to, rubber.

In some embodiments, the digital simulation model may based on a proportional-integral-derivative (PID) controller block that includes a PID observer. In some aspects, the PID observer models frictional mechanics of the stopper relative to a surface of the pre-filled vial with which the stopper is engaged in accordance with a PID friction compensation model. In some particular embodiments, the PID friction compensation model is based at least in part upon elastomer-glass surface asperities and frictional characteristics inherent thereto.

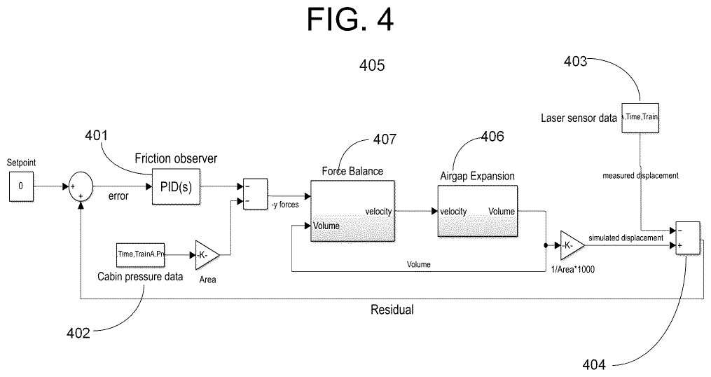

FIG. 4 illustrates, in an example embodiment, architecture 405 of proportional-integral-derivative (PID) controller block 205 for digital simulation of operational integrity of pre-filled vial 100. In embodiments, PID controller block 205 includes friction observer 401 in conjunction with force balance 407 model, airgap expansion model 406, laser sensor data 403, cabin pressure data 402, and. simulated stopper displacement 404. Friction observer 401 is used for friction compensation based on stopper 101 displacement tracking.

In some embodiments, the simulation model structure may be derived in part on:

$$m \frac{dv}{dt} = ( \frac{nRT}{V ( t )} - {P}_{atm} ( t ) ) A - f$$

$$\frac{dV}{dt} = vA$$

where m represents the stopper mass, v is the stopper velocity, and the airgap pressure is product of n moles of air, the ideal gas constant R, and the absolute temperature T divided by the airgap volume V; furthermore, Pₐₜₘ is the atmospheric or cabin pressure, A the cross-sectional area, f is the friction force, and the pressure differential ΔP is represented by the difference equation in parenthesis. Equation 2 reflects the coupling between the stopper's velocity and the airgap 102 volume.

In related aspects, friction observation/compensation may be based implementation detail for PID controller block 405 as follows:

$$u ( t ) = {k}_{c} e ( t ) + \frac{{k}_{c}}{{τ}_{i}} {\int }_{0}^{t} e ( τ ) d τ + {k}_{c} {τ}_{d} \frac{de ( t )}{dt}$$

With transfer function implemented, in one specific simulation embodiment:

$$u ( s ) = P + I ( \frac{1}{s} ) + D ( \frac{Ns}{s + N} )$$

PID tuning parameters may be automatically estimated, in a particular simulation embodiment, using optimization techniques to minimize the sum squared error of the residual signal, where the cost function is given by:

$$F ( x ) = {\sum }_{t = 0}^{t = N} {r ( t )}^{2}$$

In one embodiment, inputs to the digital simulation model, and outputs therefrom, may be in accordance with:

| Inputs | Outputs | Key Assumptions |
|---|---|---|
| Cabin pressure profile ^{M} | Stopper displacement | |
| Laser displacement profile ^{M} | Stopper velocity | Stopper does not interact with the water in |
| | | the syringe |
| Initial airgap volume ^{M} | Stopper friction | The air in the airgap behaves as an ideal |
| Initial airgap pressure ^{A} | | gas |
| Initial airgap temperature ^{A} | | Probabilistic events such as stick-slip motion |
| Moles of air in airgap ^{C} | | are neglected |
| Cross-sectional area ^{C} | | Isothermal process (298° K) |
| PID tuning parameters ^{E} | | |

Note:
superscripts denote
measured ^{M},
assumed ^{A},
calculated ^{C},
or estimated ^{E}

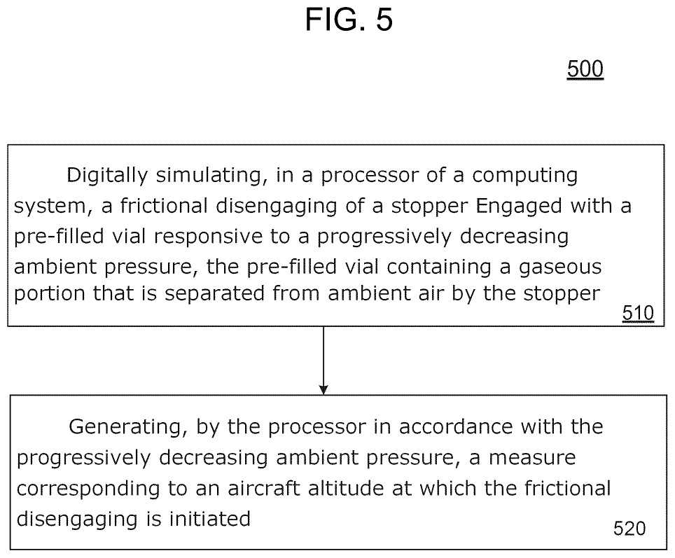

FIG. 5 illustrates, in an example embodiment, method 500 of operation in digital simulation of operational integrity of a pre-filled vial. Examples of method steps described herein are related to deployment and use of digital simulation computing system 300 used in conjunction with any components, systems and steps and techniques disclosed in conjunction with FIGS. 1-4 herein. According to some embodiments, the techniques are performed in processor 301 executing one or more sequences of software logic instructions that constitute vial digital simulation logic module 210. In embodiments, instructions constituting vial digital simulation logic module 210 may be read into memory 302 from machine-readable medium, such as memory storage devices. Executing the instructions of vial digital simulation logic module 210 stored in memory 302 causes processor 301 to perform the process steps described herein, including process steps of FIG. 5. In alternative implementations, at least some hard-wired circuitry, including but not limited to application specific integrated circuits (ASICS) and field-programmable gate arrays (FPGA's) may be used in place of, or in combination with, the software logic instructions to implement examples described herein. Thus, the examples described herein are not limited to any particular combination of hardware circuitry and software instructions.

At step 510, digitally simulating, in a processor 301 of computing system 300, a frictional disengaging of a stopper 101 that is engaged with pre-filled vial 100 responsive to a progressively decreasing ambient pressure, pre-filled vial 100 containing a gaseous portion 102 that is separated from ambient air by the stopper 101.

At step 520, generating, by processor 301 in accordance with the progressively decreasing ambient pressure, a measure corresponding to an aircraft altitude at which the frictional disengaging is initiated.

In some embodiments, the pre-filled vial comprises a pre-filled syringe. The vial may be constructed of a glass or a polymer material, and also any combination thereof. The stopper may be constructed of an elastomer material, such as, but not limited to, rubber.

In embodiments, the digital simulation model may based on a proportional-integral-derivative (PID) controller block that includes a PID observer. In some aspects, the PID observer models frictional mechanics of the stopper relative to a surface of the pre-filled vial with which the stopper is engaged in accordance with a PID friction compensation model. In some particular embodiments, the PID friction compensation model is based at least in part upon elastomer-glass surface asperities and frictional characteristics inherent thereto.

In some embodiments, the simulation model comprises a set of inputs to the PID controller block, the set of inputs comprising one or more of a measured aircraft cabin pressure profile, a measured laser displacement profile, a measured initial volume of the gaseous portion, an assumed initial pressure of the gaseous portion, an assumed initial temperature of the gaseous portion, a calculated measure of a quantity of moles of gas in the gaseous portion, a calculated cross sectional area of the pre-filled vial, and a set of PID tuning parameters.

In some aspects, the simulation model comprises a set of outputs from the PID controller block, the set of outputs comprising one or more of a stopper displacement, a stopper velocity and a stopper friction characteristic. In embodiments, the corresponding aircraft altitude at which the frictional disengaging is initiated may be generated based at least in part on the set of outputs.

Although embodiments are described in detail herein with reference to the accompanying drawings, it is contemplated that the disclosure herein is not limited to only such literal embodiments. As such, modifications and equivalents of the digital computing system-based simulation of operational integrity of pre-filled vials, and variations in sequence of the method steps in conjunction with varying combinations of features disclosed herein will be apparent to practitioners skilled in this art. Accordingly, it is intended that the scope of the invention be defined by the following claims and their equivalents. Furthermore, it is contemplated that a particular feature described either individually or as part of an embodiment can be combined with other individually described features, or parts of other embodiments described herein. Thus, absence of any described particular combinations of such does not preclude the inventor from claiming rights to such combinations.

What is claimed is:

1. A method of digitally simulating operational integrity of a pre-filled vial, the method comprising:
simulating, in a processor of a computing system, a frictional disengaging of a stopper from the pre-filled vial responsive to a progressively decreasing ambient pressure, the pre-filled vial containing a gaseous portion that is separated from ambient air by the stopper; and
generating, by the processor in accordance with the progressively decreasing ambient pressure, a measure corresponding to an aircraft altitude at which the frictional disengaging is initiated.

2. The method of claim 1 wherein the pre-filled vial comprises a pre-filled syringe.

3. The method of claim 1 wherein the vial comprises at least one of a glass and a polymer material.

4. The method of claim 1 wherein the stopper comprises an elastomer material.

5. The method of claim 1 wherein simulating comprises a simulation model based on a proportional-integral-derivative (PID) controller block that includes a PID observer.

6. The method of claim 5 wherein the PID observer models frictional mechanics of the stopper relative to a surface of the pre-filled vial with which the stopper is engaged in accordance with a PID friction compensation model.

7. The method of claim 6 wherein the PID friction compensation model is based at least in part upon elastomer-glass surface asperities.

8. The method of claim 5 wherein the simulation model comprises a set of inputs to the PID controller block, the set of inputs comprising one or more of a measured aircraft cabin pressure profile, a measured laser displacement profile, a measured initial volume of the gaseous portion, an assumed initial pressure of the gaseous portion, an assumed initial temperature of the gaseous portion, a calculated measure of a quantity of moles of gas in the gaseous portion, a calculated cross sectional area of the pre-filled vial, and a set of PID tuning parameters.

9. The method of claim 5 wherein the simulation model comprises a set of outputs from the PID controller block, the set of outputs comprising one or more of a stopper displacement, a stopper velocity and a stopper friction characteristic.

10. The method of claim 9 wherein the corresponding aircraft altitude at which the frictional disengaging is initiated is generated based at least in part on the set of outputs.

11. A computer simulation system that simulates operational integrity of a pre-filled vial, the computer simulation system comprising:
one or more processors; and
a memory storing instructions executable in the one or more processors, the instructions when executed causing the one or more processors to implement operations comprising:
instantiating a simulation module that simulates frictional disengaging of a stopper from a pre-filled vial responsive to a progressively decreasing ambient pressure, the pre-filled vial including a gaseous portion that is separated from ambient air by the stopper; and
instantiating an output module that generates, in accordance with the progressively decreasing ambient pressure, a measure corresponding to an aircraft altitude at which the frictional disengaging is initiated.

12. The computer simulation system of claim 11 wherein the pre-filled vial comprises a pre-filled syringe.

13. The computer simulation system of claim 11 wherein the vial comprises at least one of a glass and a polymer material.

14. The computer simulation system of claim 11 wherein the stopper comprises an elastomer material.

15. The computer simulation system of claim 11 wherein simulating comprises a simulation model based on a proportional-integral-derivative (PID) controller block that includes a PID observer.

16. The computer simulation system of claim 15 wherein the PID observer models frictional mechanics of the stopper relative to a surface of the pre-filled vial with which the stopper is engaged in accordance with a PID friction compensation model.

17. The computer simulation system of claim 16 wherein the PID friction compensation model is based at least in part upon elastomer-glass surface asperities.

18. The computer simulation system of claim 15 wherein the simulation model comprises a set of inputs to the PID controller block, the set of inputs comprising one or more of a measured aircraft cabin pressure profile, a measured laser displacement profile, a measured initial volume of the gaseous portion, an assumed initial pressure of the gaseous portion, an assumed initial temperature of the gaseous portion, a calculated measure of a quantity of moles of gas in the gaseous portion, a calculated cross sectional area of the pre-filled vial, and a set of PID tuning parameters.

19. The computer simulation system of claim 15 wherein the simulation model comprises a set of outputs from the PID controller block, the set of outputs comprising one or more of a stopper displacement, a stopper velocity and a stopper friction characteristic.

20. A non-transitory computer readable memory storing instructions that are executable in one or more processors, the instructions when executed causing the one or more processors to implement operations comprising:
instantiating a simulation module that simulates frictional disengaging of a stopper from a pre-filled vial responsive to a progressively decreasing ambient pressure, the pre-filled vial including a gaseous portion that is separated from ambient air by the stopper; and
instantiating an output module that generates, in accordance with the progressively decreasing ambient pressure, a measure corresponding to an aircraft altitude at which the frictional disengaging is initiated.
